(19) United States
(12) Patent Application Publication
(10) Pub. No.: US 2015/0226648 A1
(43) Pub. Date: Aug. 13, 2015

(54) SAMPLE PROCESSING APPARATUS AND METHOD

(71) Applicant: KABUSHIKI KAISHA TOSHIBA, Tokyo (JP)

(72) Inventor: Sinichi FURUKAWA, Yokohama-Shi (JP)

(21) Appl. No.: 14/305,323

(22) Filed: Jun. 16, 2014

Related U.S. Application Data
(60) Provisional application No. 61/938,041, filed on Feb. 10, 2014.

(51) Int. Cl. G01N 1/28; G01N 1/44; H01J 37/10; H01J 37/30; H01J 37/08

(52) U.S. Cl. CPC G01N 1/28; H01J 37/30; H01J 37/08; H01J 37/10; G01N 1/44

(57) ABSTRACT

In one embodiment, a sample processing apparatus includes a sample stage including electrodes on which a sample is to be placed, and a polarity setting module to set polarity of each electrode to first or second polarity. The apparatus further includes a beam generator to irradiate, with a beam, a portion of the sample placed on an electrode with the second polarity. The apparatus further includes a leading edge recognition module to recognize a leading edge of the sample, and a measuring module to measure a positional displacement between the leading edge and the electrode with the second polarity. The apparatus further includes a position changing module to change a relative position between the sample and the beam generator, based on the positional displacement measured by the measuring module, and a polarity changing module to change polarity of an electrode under the leading edge to the second polarity.

### CROSS REFERENCE TO RELATED APPLICATION

This application is based upon and claims the benefit of priority from the prior U.S. Provisional Patent Application No. 61/938,041 filed on Feb. 10, 2014, the entire contents of which are incorporated herein by reference.

### FIELD

Embodiments described herein relate to a sample processing apparatus and method.

### BACKGROUND

When a sample is processed using an ion beam such as a focused ion beam (FIB), the sample may be moved on a sample stage due to a difference in temperature between the sample and the sample stage. This is referred to as a drift phenomenon. The occurrence of the drift phenomenon displaces a processing target position of the sample and an irradiation position of the ion beam, so that the processing target position of the sample may not be irradiated with the ion beam.

### BRIEF DESCRIPTION OF THE DRAWINGS

FIGS. 1A and 1B are cross-sectional views schematically showing a configuration of a sample processing apparatus of a first embodiment;

FIG. 2 is a top view schematically showing a configuration of a sample stage of the first embodiment;

FIG. 3 shows a flow chart describing a sample processing method of the first embodiment;

FIGS. 4A and 4B are cross-sectional views schematically showing a configuration of the sample processing apparatus of a modification of the first embodiment;

FIGS. 5A and 5B are cross-sectional views schematically showing a configuration of a sample processing apparatus of a second embodiment; and

FIGS. 6A and 6B are cross-sectional views schematically showing a configuration of a sample processing apparatus of a third embodiment.

### DETAILED DESCRIPTION

Embodiments will now be explained with reference to the accompanying drawings.

In one embodiment, a sample processing apparatus includes a sample stage including electrodes on which a sample is to be placed, and a polarity setting module configured to set polarity of each electrode of the sample stage to first or second polarity. The apparatus further includes a beam generator configured to irradiate, with a beam, a portion of the sample placed on an electrode with the second polarity. The apparatus further includes a leading edge recognition module configured to recognize a leading edge of the sample, and a measuring module configured to measure a positional displacement between the leading edge of the sample recognized by the leading edge recognition module and the electrode with the second polarity. The apparatus further includes a position changing module configured to change a relative position between the sample and the beam generator, based on the positional displacement measured by the measuring module, and a polarity changing module configured to change polarity of an electrode under the leading edge of the sample to the second polarity.

### First Embodiment

### (1) Sample Processing Apparatus of First Embodiment

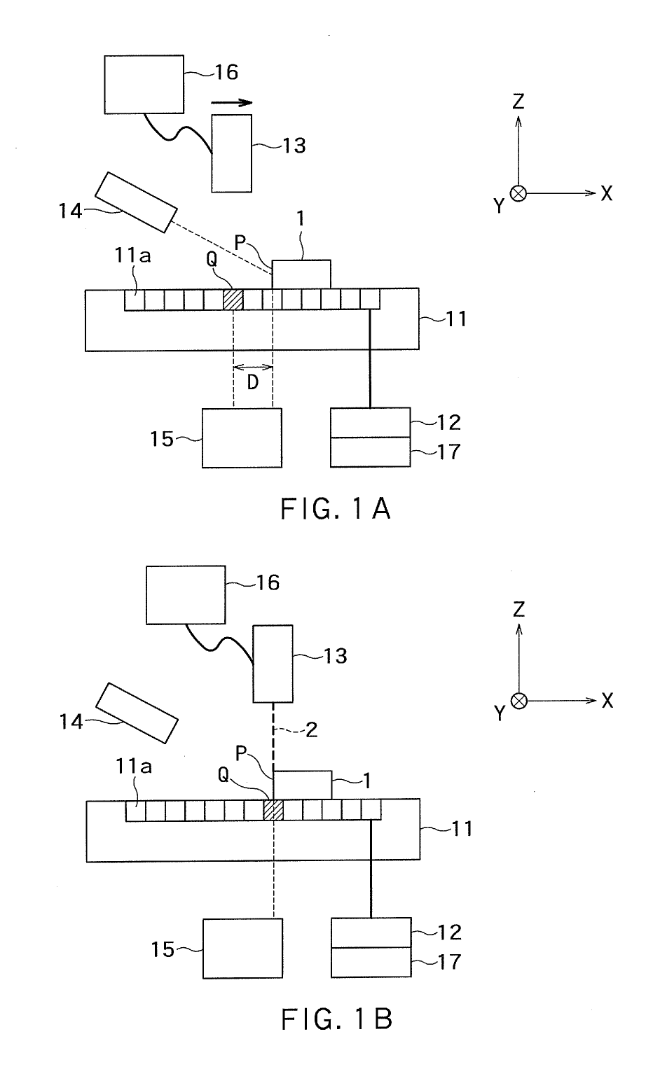

FIGS. 1A and 1B are cross-sectional views schematically showing a configuration of a sample processing apparatus of a first embodiment. The apparatus of the first embodiment is an FIB processing apparatus for processing a sample 1 using an ion beam (FIB) 2. FIG. 1A shows the apparatus before generating the ion beam 2. FIG. 1B shows the apparatus while generating the ion beam 2.

The sample processing apparatus of the present embodiment includes a sample stage 11, a polarity setting module 12, an FIB generator 13 as an example of a beam generator, a leading edge recognition module 14, a measuring module 15, a generator moving module 16 as an example of a position changing module, and a polarity changing module 17.

(Sample Stage 11)

The sample stage 11 includes electrodes 11a on which the sample 1 is to be placed. An example of a planer shape of the sample stage 11 is a square shape with an area of 5 cm×5 cm. An example of a planer shape of each electrode 11a is a square shape with an area of 10 nm×10 nm. The sample stage 11 with the electrodes 11a can be manufactured by a semiconductor manufacturing process, for example. Electrodes 11a adjacent to each other are electrically separated by an insulator, for example.

An example of the sample 1 is a block which is cut from a semiconductor wafer. An example of a shape of the sample 1 is a rectangular parallelepiped shape whose length of each side is approximately 1 to 2 cm. If the sample 1 is a semiconductor itself, the sample stage 11 is set to a size enough to place the semiconductor wafer thereon.

FIGS. 1A and 1B show X and Y directions which are parallel with a top face of the sample stage 11 and perpendicular to each other, and a Z direction which is perpendicular to the top face of the sample stage 11. In this specification, +Z direction is taken as an upward direction and −Z direction is taken as a down direction. For example, a positional relationship between the sample 1 and the sample stage 11 is described that the sample stage 11 is located below the sample 1.

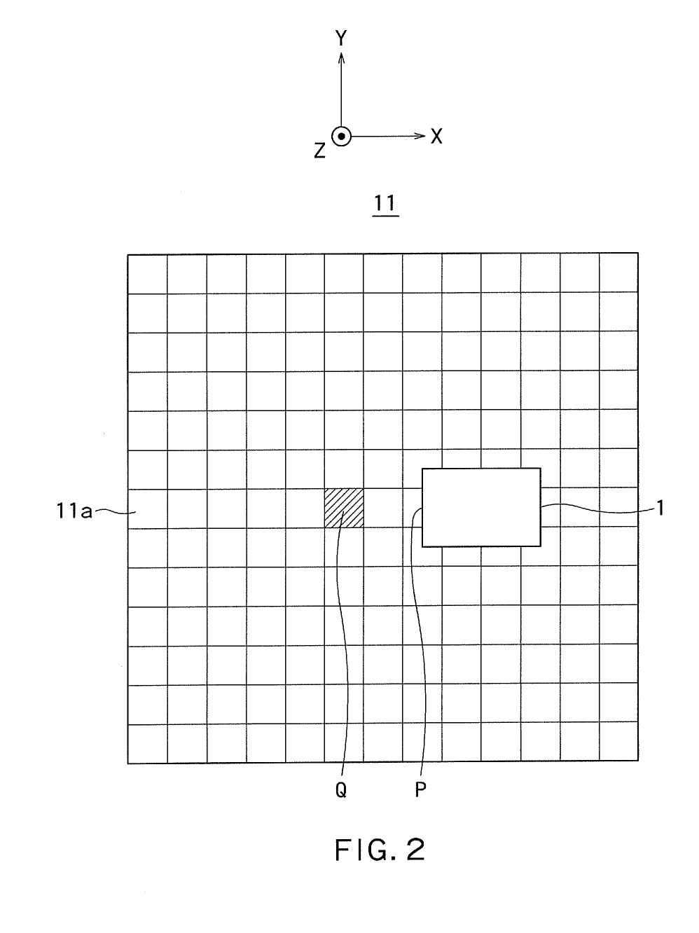

FIG. 2 is a top view schematically showing a configuration of the sample stage 11 of the first embodiment. The electrodes 11a of the present embodiment are arranged in a two-dimensional lattice shape, more specifically, in a two-dimensional square lattice shape as shown in FIG. 2.

The configuration of the sample processing apparatus of the present embodiment is further described below with reference to FIGS. 1A and 1B.

(Polarity Setting Module 12)

The polarity setting module 12 sets polarity of each electrode 11a of the sample stage 11 to positive or negative polarity. The positive polarity is an example of first polarity. The negative polarity is an example of second polarity. The polarity setting module 12 of the present embodiment applies a positive potential which is an example of a first potential to a positive electrode, and applies a negative potential which is an example of a second potential different from the first potential to a negative electrode.

The polarity setting module 12 sets the polarity of one electrode 11a (or several electrodes 11a) to the negative polarity, and sets the polarity of the other electrodes 11a to the positive polarity. FIGS. 1A and 1B show that the polarity of an electrode Q is set to the negative polarity. The reason that the position of the electrode Q in FIG. 1A and the position of the electrode Q in FIG. 1B are different from each other is described later.

(FIB Generator 13)

The FIB generator 13 irradiates, with the ion beam 2, a portion of the sample 1 placed on the electrode Q having the negative polarity. The ion beam 2 is an example of a beam and a charged particle beam. The ion beam 2 of the present embodiment has a positive charge. Therefore, the ion beam 2 generated by the FIB generator 13 is attracted by the electrode Q with the negative polarity. As a result, the portion of the sample 1 placed on the electrode Q is irradiated with the ion beam 2. For this reason, the sample processing apparatus of the present embodiment sets polarity of an electrode 11a under a processing target position of the sample 1 to the negative polarity.

As described above, FIG. 1A shows the sample processing apparatus before generating the ion beam 2, and FIG. 1B shows the sample processing apparatus while generating the ion beam 2. The processes by the leading edge recognition module 14, the measuring module 15, the generator moving module 16 and the polarity changing module 17 are performed before the processes shown in FIG. 1B are performed.

(Leading Edge Recognition Module 14)

The leading edge recognition module 14 recognizes a leading edge P of the sample 1 which is the processing target position of the sample 1. The leading edge recognition module 14 of the present embodiment recognizes the leading edge P of the sample 1 by irradiating the sample 1 with an electromagnetic wave or an acoustic wave. Examples of the electromagnetic wave include a light wave, an infrared ray, a radio wave, an X ray and the like. Examples of the acoustic wave include an ultrasonic wave and the like. The leading edge recognition module 14 of the present embodiment can recognize where the sample 1 is positioned on the sample stage 11.

(Measuring Module 15)

The measuring module 15 measures a positional displacement between the leading edge P of the sample 1 recognized by the leading edge recognition module 14 and the electrode Q with the negative polarity. A sign D shown in FIG. 1A denotes a positional displacement amount measured by the measuring module 15. The positional displacement amount D may be represented by a difference in X and Y coordinates between the leading edge P of the sample 1 and the electrode Q, or may be represented by a distance and an angle between the leading edge P of the sample 1 and the electrode Q. The measuring module 15 may measure the positional displacement between the leading edge P of the sample 1 and a center of the electrode Q, or may measure the positional displacement between the leading edge P of the sample 1 and an end of the electrode Q. The positional displacement measured by the measuring module 15 is fed back to the generator moving module 16 and the polarity changing module 17.

(Generator Moving Module 16)

The generator moving module 16 changes a relative position between the sample 1 and the FIB generator 13, based on the positional displacement measured by the measuring module 15. More specifically, the generator moving module 16 moves the position of the FIB generator 13, based on the positional displacement measured by the measuring module 15. FIGS. 1A and 1B respectively show the FIB generator 13 before and after the FIB generator 13 is moved. The generator moving module 16 moves the FIB generator 13 to a position immediately above the leading edge P of the sample 1.

(Polarity Changing Module 17)

The polarity changing module 17 changes polarity of an electrode 11a under the leading edge P of the sample 1 recognized by the leading edge recognition module 14 to the negative polarity, based on the positional displacement measured by the measuring module 15. This changes the position of the electrode Q from the position shown in FIG. 1A to the position shown in FIG. 1B. As similar to the polarity setting module 12, the polarity changing module 17 applies the positive potential to the positive electrode and the negative potential to the negative electrode.

The process performed by the generator moving module 16 moves the FIB generator 13 to the position immediately above the leading edge P of the sample 1. Also, the process performed by the polarity changing module 17 eliminates the positional displacement between the leading edge P of the sample 1 and the electrode Q with the negative polarity. The FIB generator 13 then irradiates the leading edge P of the sample 1 placed on the electrode Q with the ion beam 2. In this way, the sample processing apparatus of the present embodiment can accurately irradiate the leading edge P of the sample 1 which is the processing target position of the sample 1.

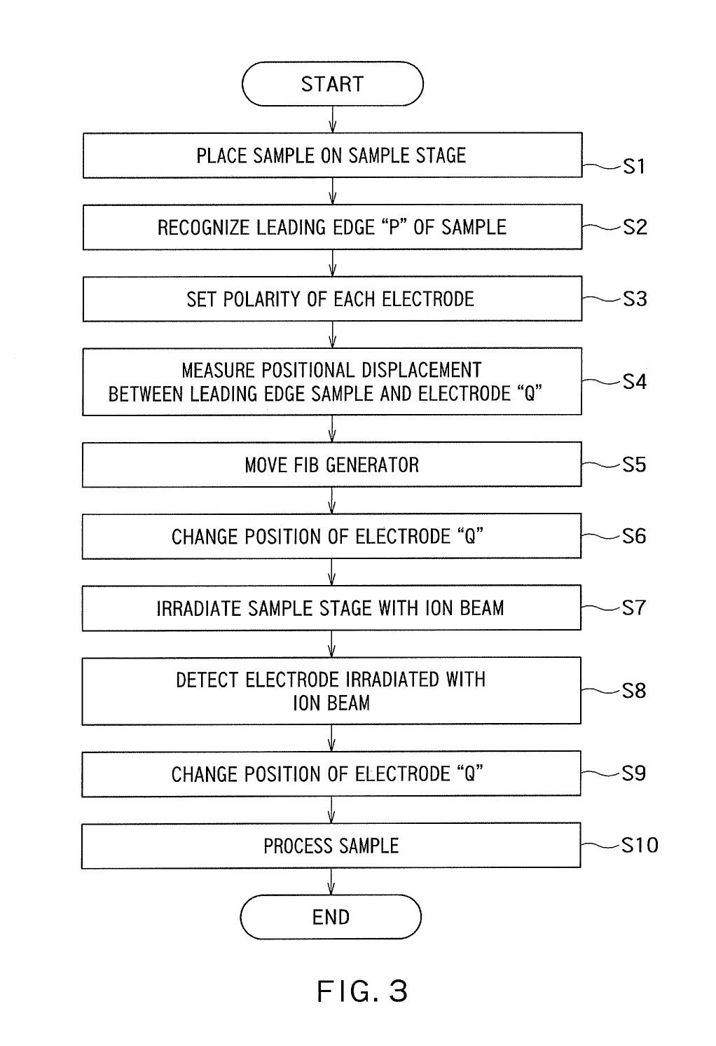

The sample processing apparatus of the present embodiment measures the positional displacement by the leading edge recognition module 14 and the measuring module 15, and eliminates the positional displacement by the generator moving module 16 and the polarity changing module 17. After the positional displacement is measured and eliminated by these modules, the sample processing apparatus of the present embodiment may further measure and eliminate finer positional displacement between the leading edge P of the sample 1 and the electrode Q. In other words, the measurement and elimination of the positional displacement in the present embodiment may be a two-step process including a first step of measuring and eliminating rough positional displacement and a second step of measuring and eliminating fine positional displacement. An example of the two-step process is described with reference to FIG. 3.

### (2) Sample Processing Method of First Embodiment

FIG. 3 shows a flow chart describing a sample processing method of the first embodiment.

First, the sample 1 to be processed is placed on the sample stage 11 (step S1). Next, the leading edge recognition module 14 recognizes the leading edge P of the sample 1 (step S2). The polarity setting module 12 then sets polarity of each electrode 11a to the positive or negative polarity (step S3). At this time, the polarity setting module 12 sets polarity of an electrode 11a near the leading edge P of the sample 1 (electrode Q) to the negative polarity and sets polarity of the other electrodes 11a to the positive polarity.

The processing in step S3 may be performed by using the result of the processing in step S2. More specifically, the polarity setting module 12 may select the electrode 11a (the electrode Q) whose polarity is set to the negative polarity by using the result of recognizing the leading edge P by the leading edge recognition module 14. On the other hand, in a case where the processing in step S3 is performed without using the result of the processing in step S2, the processing in step S3 may be performed before the processing in step S2.

Next, the measuring module 15 measures the positional displacement between the leading edge P of the sample 1 recognized by the leading edge recognition module 14 and the electrode Q (step S4). The generator moving module 16 then moves the FIB generator 13 to the position immediately above the leading edge P of the sample 1, based on the positional displacement measured by the measuring module 15 (step S5). As a result, the position of the FIB generator 13 is roughly adjusted to the position of the leading edge P of the sample 1. The polarity changing module 17 then changes the polarity of the electrode 11a under the leading edge P of the sample 1 recognized by the leading edge recognition module 14 to the negative polarity (step S6). As a result, the position of the electrode Q is changed, and the positional displacement between the leading edge P of the sample 1 and the electrode Q is roughly eliminated.

Next, the FIB generator 13 irradiates the sample stage 11 with the ion beam 2 (step S7). A controller (unshown) of the sample stage 11 then detects an electrode 11a irradiated with the ion beam 2 (step S8). The polarity changing module 17 then changes the polarity of the electrode 11a detected by the controller of the sample stage 11 to the negative polarity (step S9). As a result, the position of the electrode Q is changed, and the fine positional displacement between the leading edge P of the sample 1 and the electrode Q is eliminated.

Next, the FIB generator 13 irradiates the leading edge P of the sample 1 positioned on the electrode Q with the ion beam 2 (step S10). In this way, the sample 1 is processed by the ion beam 2.

When the two-step process such as that in FIG. 3 is performed, step S6 may be omitted. In other words, the steps of changing the position of the electrode Q are unified into step S9.

When the positional displacement between the leading edge P of the sample 1 and the electrode Q is generated during processing the sample 1, step S7 to S9 may be performed again to eliminate this positional displacement.

### (3) Sample Processing Apparatus of Modification of First Embodiment

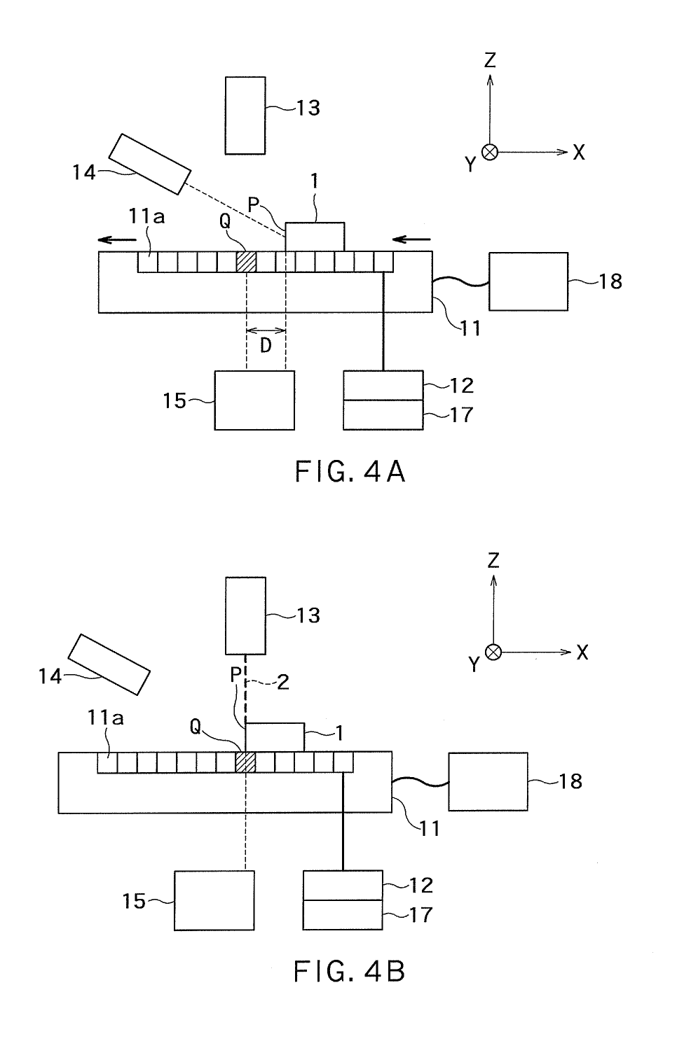

FIGS. 4A and 4B are cross-sectional views schematically showing a configuration of the sample processing apparatus of a modification of the first embodiment.

The sample processing apparatus of this modification includes a sample stage moving module 18 instead of the generator moving module 16. The sample stage moving module 18 is an example of the position changing module.

As similar to the generator moving module 16, the sample stage moving module 18 changes the relative position between the sample 1 and the FIB generator 13, based on the positional displacement measured by the measuring module 15. However, the sample stage moving module 18 moves the position of the sample stage 11, based on the positional displacement measured by the measuring module 15. FIGS. 4A and 4B respectively show the sample stage 11 before and after the sample stage 11 is moved. The sample stage moving module 18 moves the sample stage 11 to a position where the leading edge P of the sample 1 is immediately below the FIB generator 13.

In general, a moving module of the sample stage 11 can be more easily realized than a moving module of the FIB generator 13. Therefore, the sample stage moving module 18 has an advantage that it can be more easily realized than the generator moving module 16.

On the other hand, the generator moving module 16 has an advantage that a change in position of the sample 1 associated with the movement of the FIB generator 13 can be prevented.

As described above, the sample processing apparatus of the present embodiment includes the generator moving module 16 or the sample stage moving module 18 which changes the relative position between the sample 1 and the FIB generator 13 based on the result of measurement on the positional displacement between the leading edge P of the sample 1 and the electrode Q, and the polarity changing module 17 which changes the position of the electrode Q based on the result of measurement on the positional displacement between the leading edge P of the sample 1 and the electrode Q or the like.

Therefore, according to the present embodiment, even if the drift phenomenon is caused by a difference in temperature between the sample 1 and the sample stage 11, the relative position between the sample 1 and the FIB generator 13 and the position of the electrode Q can be adjusted to proper positions. Accordingly, the present embodiment makes it possible to accurately irradiate the leading edge P of the sample 1 which is the processing target position of the sample 1 with the ion beam 2, thereby allowing an accuracy of FIB process to be improved.

### Second Embodiment

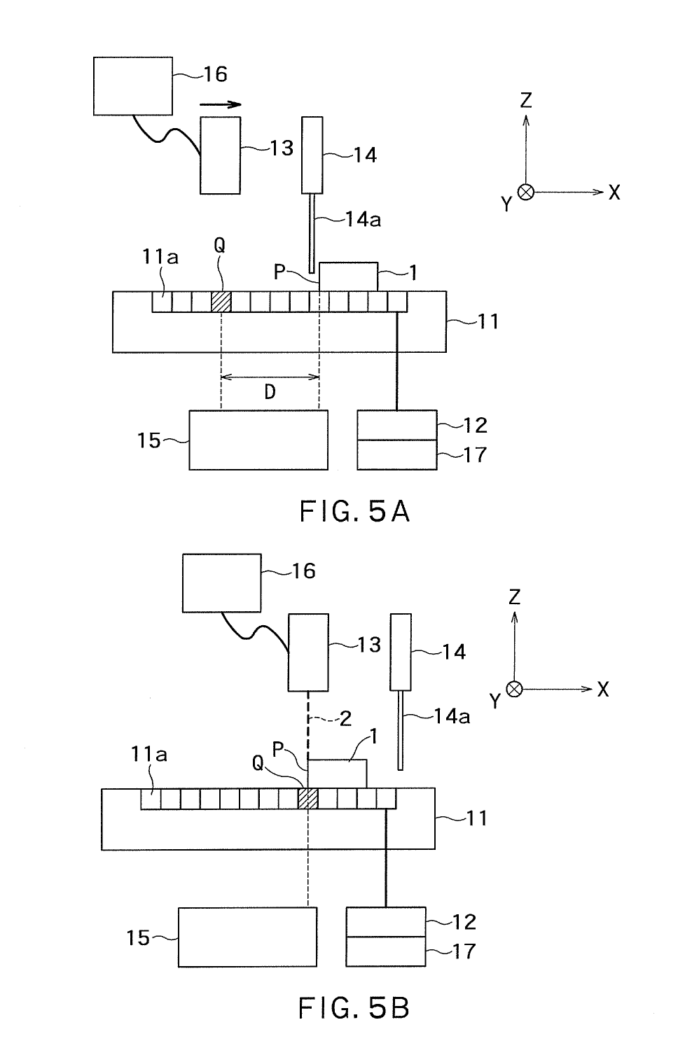

FIGS. 5A and 5B are cross-sectional views schematically showing a configuration of a sample processing apparatus of a second embodiment.

The leading edge recognition module 14 of the present embodiment includes a fine needle 14a. The leading edge recognition module 14 of the present embodiment recognizes the leading edge P of the sample 1 by bringing the needle 14a in contact with the sample 1. The needle 14a is an example of an object brought into contact with the sample 1.

The leading edge recognition module 14 of the second embodiment has an advantage that even if an electromagnetic wave or an acoustic wave exists in the sample processing apparatus, it can accurately recognize the leading edge P of the sample 1. On the other hand, the leading edge recognition module 14 of the first embodiment has an advantage that it can easily recognize the leading edge P of the sample 1 in a non-contact manner.

### Third Embodiment

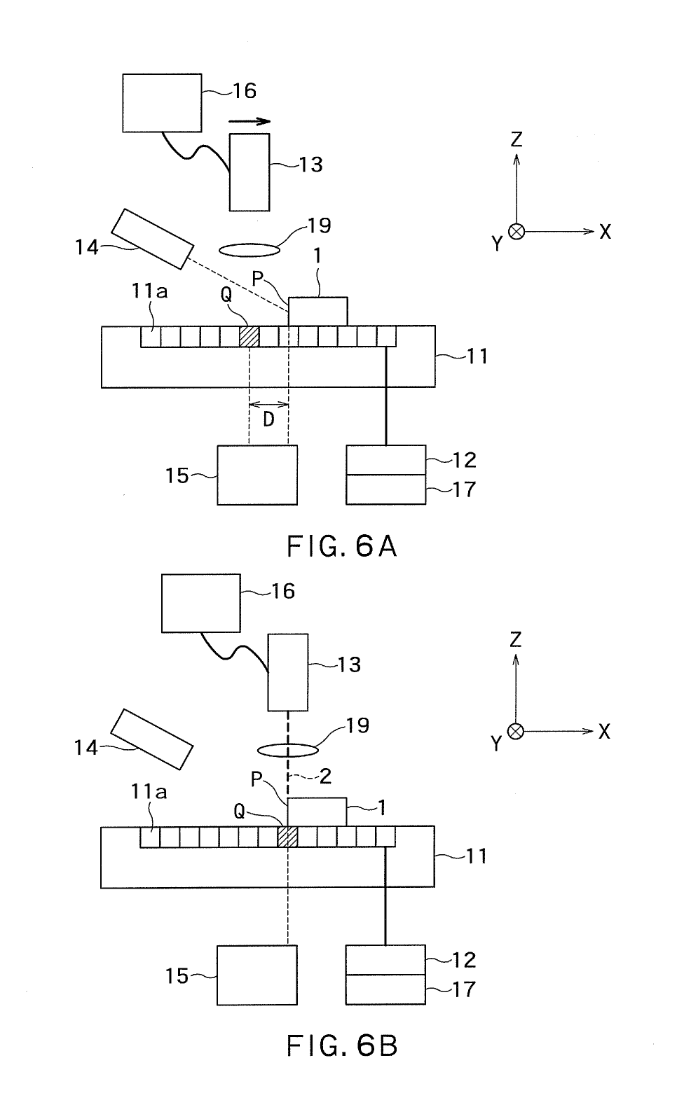

FIGS. 6A and 6B are cross-sectional schematically views showing a configuration of a sample processing apparatus of a third embodiment.

The sample processing apparatus of the present embodiment includes a lens 19 for focusing the ion beam 2 from the FIB generator 13 onto the sample 1, as well as the components of the sample processing apparatus of the first or second embodiment. The lens 19 of the present embodiment is a convex lens. The position of the lens 19 of the present embodiment is fixed with respect to the FIB generator 13. Therefore, when the generator moving module 16 moves the FIB generator 13, the lens 19 is also moved with the FIB generator 13.

The sample processing apparatus of the present embodiment can irradiate the sample 1 with the ion beam 2 thinned by the lens 19. Therefore, the present embodiment makes it possible to process the sample 1 more finely and accurately. Furthermore, according to the present embodiment, the position of the lens 19 is fixed with respect to the FIB generator 13 to allow the ion beam 2 from the FIB generator 13 to be focused onto the sample 1 even if the generator moving module 16 changes the relative position between the sample 1 and the FIB generator 13.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A sample processing apparatus comprising:
a sample stage including electrodes on which a sample is to be placed;
a polarity setting module configured to set polarity of each electrode of the sample stage to first or second polarity;
a beam generator configured to irradiate, with a beam, a portion of the sample placed on an electrode with the second polarity;
a leading edge recognition module configured to recognize a leading edge of the sample;
a measuring module configured to measure a positional displacement between the leading edge of the sample recognized by the leading edge recognition module and the electrode with the second polarity;
a position changing module configured to change a relative position between the sample and the beam generator, based on the positional displacement measured by the measuring module; and
a polarity changing module configured to change polarity of an electrode under the leading edge of the sample to the second polarity.

2. The apparatus of claim 1, wherein the position changing module moves a position of the beam generator, based on the positional displacement measured by the measuring module.

3. The apparatus of claim 1, wherein the position changing module moves a position of the sample stage, based on the positional displacement measured by the measuring module.

4. The apparatus of claim 1, wherein the leading edge recognition module recognizes the leading edge of the sample by irradiating the sample with an electromagnetic wave or an acoustic wave.

5. The apparatus of claim 1, wherein the leading edge recognition module recognizes the leading edge of the sample by bringing an object into contact with the sample.

6. The apparatus of claim 1, further comprising a lens configured to focus the beam onto the sample.

7. The apparatus of claim 1, wherein the electrodes are arranged in a two-dimensional lattice shape.

8. The apparatus of claim 1, wherein the beam from the beam generator is a charged particle beam.

9. The apparatus of claim 8, wherein the charged particle beam from the beam generator has the first polarity.

10. The apparatus of claim 1, wherein the polarity setting module and the polarity changing module apply a first potential to an electrode with the first polarity, and apply a second potential different from the first potential to an electrode with the second polarity.

11. A sample processing method comprising:
placing a sample on a sample stage which includes electrodes;
recognizing a leading edge of the sample by a leading edge recognition module;
setting polarity of each electrode of the sample stage to first or second polarity;
measuring a positional displacement between the leading edge of the sample recognized by the leading edge recognition module and an electrode with the second polarity by a measuring module;
changing a relative position between the sample and a beam generator, based on the positional displacement measured by the measuring module;
changing polarity of an electrode under the leading edge of the sample to the second polarity; and
irradiating, with a beam from the beam generator, the leading edge of the sample positioned on the electrode with the second polarity.

12. The method of claim 11, wherein the changing of the relative position comprises moving a position of the beam generator, based on the positional displacement measured by the measuring module.

13. The method of claim 11, wherein the changing of the relative position comprises moving a position of the sample stage, based on the positional displacement measured by the measuring module.

14. The method of claim 11, wherein the leading edge recognition module recognizes the leading edge of the sample by irradiating the sample with an electromagnetic wave or an acoustic wave.

15. The method of claim 11, wherein the leading edge recognition module recognizes the leading edge of the sample by bringing an object into contact with the sample.

16. The method of claim 11, wherein the beam from the beam generator is focused onto the sample by a lens.

17. The method of claim 11, wherein the electrodes are arranged in a two-dimensional lattice shape.

18. The method of claim 11, wherein the beam from the beam generator is a charged particle beam.

19. The method of claim 18, wherein the charged particle beam from the beam generator has the first polarity.

20. The method of claim 11, wherein a first potential is applied to an electrode with the first polarity, and a second potential different from the first potential is applied to an electrode with the second polarity.
